(19) United States
(12) Patent Application Publication
(10) Pub. No.: US 2023/0037713 A1
(43) Pub. Date: Feb. 9, 2023

(54) SEMICONDUCTOR PACKAGE STRUCTURE AND METHOD FOR MANUFACTURING THE SAME

(71) Applicant: Advanced Semiconductor Engineering, Inc., Kaohsiung (TW)

(72) Inventors: Wei-Tang CHU, Kaohsiung (TW); Tsu-Hsiu WU, Kaohsiung (TW); Chun Yu KO, Kaohsiung (TW)

(73) Assignee: Advanced Semiconductor Engineering, Inc., Kaohsiung (TW)

(21) Appl. No.: 17/396,602

(22) Filed: Aug. 6, 2021

(51) Int. Cl. H01L 31/0216; H01L 31/0203; H01L 31/02; H01L 31/18

(52) U.S. Cl. CPC H01L 31/02164; H01L 31/0203; H01L 31/02005; H01L 31/1876; H01L 25/10

(57) ABSTRACT

The present disclosure provides an electronic package. The electronic package includes a substrate, a first electronic component, an encapsulant, and a shielding layer. The substrate has a first upper surface, a second upper surface, and a first lateral surface extending between the first upper surface and the second upper surface. The first electronic component is disposed on the substrate. The encapsulant coves the first electronic component and the first lateral surface of the substrate. The shielding layer covers the encapsulant. The shielding layer is spaced apart from the first lateral surface of the substrate.

### BACKGROUND

### 1. Field of the Disclosure

The present disclosure relates to an electronic package and a method of manufacturing the same.

### 2. Description of Related Art

Ambient light sensors have been widely used in various electronic devices, such as smart phones, notebooks, tablets, or even in automobiles and liquid crystal (LCD) televisions. The ambient light sensors are configured to adjust the luminance of such devices so that people can adapt to the luminance of a light. A shielding layer is used on the ambient light sensor to block the ambient light sensor from interfering light signals in the surrounding environment. However, the shielding layer may be damaged during manufacturing processes and electrical tests. Therefore, it is desirable to reduce damage to the shielding layer in order to enhance the performance of the ambient light sensor.

### SUMMARY

According to some embodiments of the present disclosure, an electronic package includes a substrate, a first electronic component, an encapsulant, and a shielding layer. The substrate has a first upper surface, a second upper surface, and a first lateral surface extending between the first upper surface and the second upper surface. The first electronic component is disposed on the substrate. The encapsulant coves the first electronic component and the first lateral surface of the substrate. The shielding layer covers the encapsulant. The shielding layer is spaced apart from the first lateral surface of the substrate.

According to some embodiments of the present disclosure, an electronic package includes a substrate, a shielding layer and an encapsulant. The substrate includes a conductive layer. The substrate defines a recess at a peripheral region of the substrate, and the conductive layer is exposed from the recess. The shielding layer is electrically connected to an exposed portion of the conductive layer exposed from the recess. The encapsulant is disposed between the substrate and the shielding layer and extending into the recess of the substrate.

According to some embodiments of the present disclosure, an electronic package includes a carrier and an encapsulant. The carrier includes a conductive layer exposed by a recess at a peripheral region of the carrier. The encapsulant covers the carrier and extends into the recess of the carrier.

### BRIEF DESCRIPTION OF THE DRAWINGS

Aspects of the present disclosure are readily understood from the following detailed description when read with the accompanying figures. It should be noted that various features may not be drawn to scale. In fact, the dimensions of the various features may be arbitrarily increased or reduced for clarity of discussion.

FIG. 1 is a cross-sectional view of an electronic package in accordance with some embodiments of the present disclosure.

FIG. 2 is a cross-sectional view of an electronic package in accordance with some embodiments of the present disclosure.

FIG. 3A, FIG. 3B, FIG. 3C, FIG. 3D, FIG. 3E, FIG. 3F, FIG. 3G, FIG. 3H and FIG. 3I illustrate various stages of a method for manufacturing an electronic package in accordance with some embodiments of the present disclosure.

Common reference numerals are used throughout the drawings and the detailed description to indicate the same or similar components. The present disclosure will be more apparent from the following detailed description taken in conjunction with the accompanying drawings.

### DETAILED DESCRIPTION

The following disclosure provides many different embodiments, or examples, for implementing different features of the provided subject matter. Specific examples of components and arrangements are described below. These are, of course, merely examples and are not intended to be limiting. In the present disclosure, reference to the formation or disposal of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Embodiments of the present disclosure are discussed in detail below. It should be appreciated, however, that the present disclosure provides many applicable concepts that can be embodied in a wide variety of specific contexts. The specific embodiments discussed are merely illustrative and do not limit the scope of the disclosure.

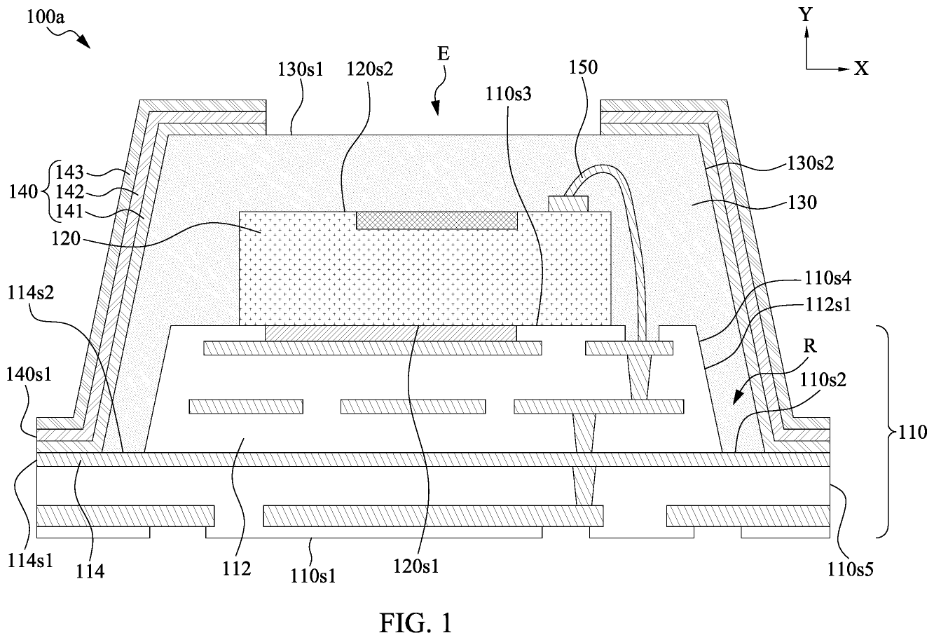

FIG. 1 is a cross-sectional view of an electronic package 100a in accordance with some embodiments of the present disclosure.

In some embodiments, the electronic package 100a may be applicable to, for example, an ambient light sensor, time of flight (ToF) sensor, proximity sensor, photo-detector module or other optical devices. However, the present disclosure is not intended to be limiting. In some embodiments, the electronic package 100a may include a semiconductor package structure. In some embodiments, the electronic package 100a may include a substrate 110, an electronic component 120, an encapsulant 130, a shielding layer 140, and an electrical connector 150.

The substrate 110 may be configured to serve as a carrier such that the electronic component 120 can be disposed thereon. The substrate 110 may provide electrical paths such that the electronic component 120 may be electrically connected to other components. The substrate 110 may include a redistribution layer (RDL). The RDL may include a dielectric structure 112, a conductive layer 114, other conductive traces and vias embedded in the dielectric structure 112.

In some embodiments, the substrate 110 may have surfaces 110s1, 110s2, 110s3, 110s4, and 110s5. The surface 110s1 (or a bottom surface or a lower surface) and the surface 110s3 (or a top surface or an upper surface) may be located on two opposite sides of the substrate 110. The surface 110s2 (or a top surface or an upper surface) and the surface 110s3 may be located at different elevations, and the surface 110s2 may be located between the surfaces 110s1 and 110s3. The surface 110s4 (or a lateral surface) may extend between the surfaces 110s2 and 110s3. The surface 110s5 (or a lateral surface) may extend between the surfaces 110s1 and 110s2. In some embodiments, the surface 110s4 of the substrate 110 is oblique with respect to the surface 110s2 of the substrate. In some embodiments, an angle between the surface 110s4 and a vertical axis (e.g., the Y-axis) is greater than an angel between the surface 110s5 and the vertical axis.

In some embodiments, the substrate 110 may define a recess R at a peripheral region of the substrate 110. The surface 110s2 and the surface 110s4 may define the recess R. The recess R may be recessed from the surface 110s3 of the substrate 110. The surface 110s2 of the substrate 110 may serve as a bottom of the recess R, and the surface 110s4 of the substrate 110 may serve as a sidewall of the recess R. In some embodiments, the angle between the surface 110s2 and the surface 110s4 may include an obtuse angle (i.e., greater than 90°). In some embodiments, a portion (e.g., the top portion or the upper portion) of the substrate 110 may be tapered along a direction toward the positive Y-axis.

The dielectric structure 112 may include a plurality of dielectric layers. The dielectric structure 112 may include, for example, Prepreg (PP), Ajinomoto build-up film (ABF), solder resist or other suitable materials. The dielectric structure 112 may include a surface 112s1 (or a lateral surface). In some embodiments, the surface 112s1 of the dielectric structure 112 may be regarded as the surface 110s4 of the substrate 110, and extend between the surfaces 110s2 and 110s3 of the substrate 110.

The conductive layer 114 may be embedded in the dielectric structure 112. In some embodiments, the conductive layer 114 is a ground layer electrically connected to ground. The conductive layer 114 may include conductive materials, such as copper (Cu), titanium (Ti), nickel (Ni), silver (Ag), aluminum (Al), gold (Au), or an alloy thereof. In some embodiments, the conductive layer 114 may include a surface 114s1 (or a lateral surface) and a surface 114s2 (or a top surface or an upper surface). The surface 114s1 of the conductive layer 114 may be exposed from the dielectric structure 112. The surface 114s1 of the conductive layer 114 may be substantially coplanar with the surface 110s5 of the substrate 110. The surface 114s2 may face the electronic component 120. In some embodiments, the surface 114s2 of the conductive layer 114 may be exposed from the recess R. In some embodiments, the surface 114s2 of the conductive layer 114 may be regarded as the surface 110s2 of the substrate 110. Although FIG. 1 illustrates that the dielectric structure 112 is divided into two portions separated by the conductive layer 114 in this cross section, it is should be noted that the dielectric structure 112 may penetrate the conductive layer 114 in other cross sections. For example, the conductive layer 114 may have, for example, a ring-shaped profile from a top view, the conductive layer 114 may define a hollow portion surrounded by the conductive layer 114, and a portion of the dielectric structure 112 may be disposed within the hollow portion of the conductive layer 114.

The electronic component 120 may be disposed on the surface 110s3 of the substrate 110. The electronic component 120 may include active components and/or passive components. The electronic component 120 may include a semiconductor die or a chip. The electronic component 120 may include a plurality of integrated circuits (ICs). The electronic component 120 may include a photo detector, sensor, transceiver, receiver, transmitter or other elements that can process optical signals and/or electrical signals. However, the present disclosure is not intended to be limited thereto. In other embodiments, The electronic component 120 may include a logic die (e.g., system-on-a-chip (SoC), central processing unit (CPU), graphics processing unit (GPU), application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies) or other electronic components. The electronic component 120 may include a backside surface 120s1 and an active surface 120s2 opposite to the backside surface 120s1. In some embodiments, the backside surface 120s1 of the electronic component 120 may face the substrate 110.

The encapsulant 130 may be disposed on the surface 110s2 of the substrate 110. In some embodiments, the encapsulant 130 may cover the electronic component 120, the surface 110s2, the surface 110s3, and the surface 110s4 of the substrate 110. In some embodiments, the encapsulant 130 may be in contact with the surface 114s2 of the conductive layer 114. In some embodiments, a portion of the surface 110s2 of the substrate 110 is not covered by the encapsulant 130. In some embodiments, a portion of the surface 114s2 of the conductive layer 114 is not covered by the encapsulant 130. The encapsulant 130 may have a surface 130s1 (or a top surface or an upper surface) and a surface 130s2 (or a lateral surface). The surface 130s2 may extend between the surface 130s1 of the encapsulant 130 and the surface 110s2 of the substrate 110. In some embodiments, the surface 130s2 of encapsulant 130 is oblique with respect to the surface 110s2 of the substrate 110. The encapsulant 130 may include insulation or dielectric material. In some embodiments, the encapsulant 130 is transparent. As used herein the term “transparent” may refer to a structure or a layer which allows a light within a specific wavelength range, such as a visible light, infrared light or light in other wavelength range, to pass through. For example, the transmittance of the encapsulant 130 may be greater than or equal to 85% at a specific wavelength range, such as 85%, 90%, 95% 97%, 99% or more. In some embodiments, the encapsulant 130 may be made of molding material that may include, for example, a Novolac-based resin, an epoxy-based resin, a silicone-based resin, or another suitable encapsulant. Suitable fillers may also be included in the encapsulant 130.

The shielding layer 140 may cover the encapsulant 130. The shielding layer 140 may be electrically connected to the conductive layer 114 of the substrate 110. In some embodiments, the shielding layer 140 may cover the surface 130s1 and the surface 130s2 of the encapsulant 130. In some embodiments, the shielding layer 140 may cover the surface 110s2 of the substrate 110 (or the surface 114s2 of the conductive layer 114). In some embodiments, the shielding layer 140 may be in contact with the surface 110s2 of the substrate 110 (or the surface 114s2 of the conductive layer 114). In some embodiments, the shielding layer 140 may be in contact with the surface 110s2 of the substrate 110 (or the surface 114s2 of the conductive layer 114) exposed from the recess R. The shielding layer 140 may cover the portion of the substrate 110 that is exposed from the encapsulant 130. In some embodiments, the shielding layer 140 may extend from the surface 130s1 of the encapsulant 130, along the surface 130s2 of the encapsulant 130, and into the recess R of the substrate 110.

The shielding layer 140 may have a surface 140s1. The surface 140s1 may be substantially coplanar with the surface 114s1 of the conductive layer 114. The surface 114s1 of the conductive layer 114 may be exposed from the shielding layer 140. In some embodiments, the shielding layer 140 is spaced apart from the surface 112s1 of the dielectric structure 112 (or the surface 110s4 of the substrate 110) by the encapsulant 130. In some embodiments, the conductive layer 114 is spaced apart from the dielectric structure 112 of the substrate 110. A portion of the encapsulant 130 may be disposed between the substrate 110 and the shielding layer 140. In some embodiments, the shielding layer 140 does not contact the surface 110s5 of the substrate 110. In some embodiments, the surface 110s5 of the substrate 110 is not substantially covered by the shielding layer 140. In some embodiments, the surface 140s1 of the shielding layer 140 is aligned with the surface 110s5 of the substrate 110. For example, the surface 140s1 of the shielding layer 140 is substantially coplanar with the surface 110s5 of the substrate 110.

In some embodiments, the shielding layer 140 may cover a first portion of the surface 130s1 of the encapsulant 130 and define an opening E exposing a second portion of the surface 130s1 of the encapsulant 130 and the electronic component 120. In some embodiments, the opening E may be configured to allow signals (e.g., light or other optical signals) to pass through and reach the active surface 120s2 of the electronic component 120. In some embodiments, the signals (e.g., light or other optical signals) may enter the electronic package 100a from the opening E, pass through the encapsulant 130 and reach the active surface 120s2 of the electronic component 120. In some embodiments, the opening E may be configured to allow signals (e.g., light or other optical signals) emitted by the electronic component 120 to pass through. The shielding layer 140 may include a multi-layered structure. For example, the shielding layer 140 may include an adhesion metal layer 141, one or more intervening metal layers 142, and a protection metal layer 143. The adhesion metal layer 141 may face the encapsulant 130. The intervening metal layer(s) 142 may be sandwiched by the adhesion metal layer 141 and protection metal layer 143. The adhesion metal layer 141 may have a relatively good adhesion ability to the encapsulant 130 to prevent the shielding layer 140 from peeling off from the encapsulant 130. The adhesion metal layer 141 may include, for example, stainless steel or other suitable materials. The intervening metal layer 142 may have a relatively good ductility and a shield ability to block the electronic component 120 from interfering signals (e.g., light or other optical signals) in the surrounding environment. The intervening metal layer 142 may include, for example, copper or other suitable materials. The protection metal layer 143 may be configured to protect the intervening metal layer 142 from oxidation. The protection metal layer 143 may include, for example, stainless steel or other suitable materials.

The electrical connector 150 may be disposed on the active surface 120s2 of the electronic component 120. The electrical connector 150 may electrically connect the electronic component 120 and the substrate 110. The electrical connector 150 may include, for example, a bonding wire. The electrical connector 150 may include Cu, Ni, Ag, or other suitable materials.

In a comparative example, the substrate or the encapsulant does not define a recess, and the sidewall of the encapsulant and the sidewall of the dielectric structure are coplanar. Further, a shielding layer is formed on such sidewalls of the encapsulant and dielectric structure of the substrate. Thus, the shielding layer is in contact with a junction of the encapsulant and the dielectric structure of the substrate. Since the difference between the thermal expansion coefficients of the dielectric structure and the encapsulant is relatively great, the shielding layer may be prone to break at the junction between the encapsulant and the dielectric structure during reliability tests at different temperatures, which may cause the electrical test results to be abnormal. In the embodiments of this disclosure, the shielding layer 140 is spaced apart from the dielectric structure 112 of the substrate 110. The shielding layer 140 is in contact with a junction of the conductive layer 114 and the encapsulant 130. Since the difference between the thermal expansion coefficients of the shielding layer 140 and the conductive layer 114 are relatively small and the shielding layer 140 has superior adhesion to the conductive layer 114, the breakage issue found at the junction between the encapsulant and the dielectric structure can be overcome and the shielding layer 140 of the electronic package 100a may remain intact during the reliability tests at different temperatures. Therefore, the shielding layer 140 may have a better ability to block the electronic package 100a from interfering signals in the surrounding environment. As a result, the yield and performance of the electronic package 100a can be enhanced.

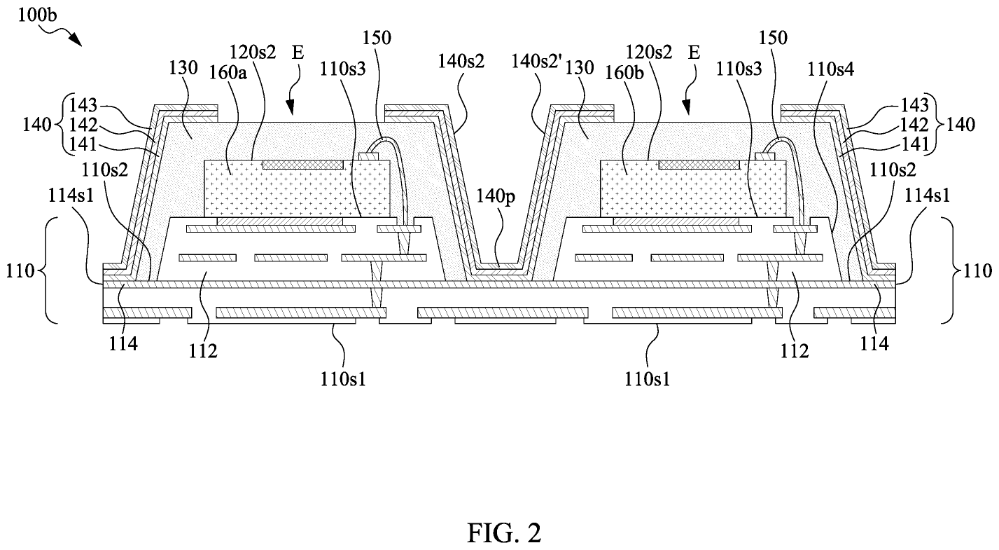

FIG. 2 is a cross-sectional view of an electronic package 100b in accordance with some embodiments of the present disclosure. In some embodiments, the electronic package 100b may include two or more repeated units, and each of the repeated units has a structure which is the same as or similar to that of the electronic package 100a.

In some embodiments, the electronic package 100b may include a semiconductor package structure. In some embodiments, the electronic package 100b may include electronic components 160a and 160b. Each of the electronic component 160a and/or 160b may be the same as or similar to the electronic component 120 illustrated in FIG. 1. The electronic component 160a and 160b may be arranged side-by-side. The electronic component 160b is blocked from the electronic component 160a by the shielding layer 140. In some embodiments, the electronic components 160a and 160b may have different functions. For example, the electronic component 160a may be a receiver, and the electronic component 160b may be a transmitter. In some embodiments, the electronic components 160a and 160b may be applicable to, for example, a ToF device or other optical or electronic devices.

In some embodiments, the shielding layer 140 may have a plane structure 140p between the electronic components 160a and 160b. The plane structure 140p of the shielding layer 140 may cover the conductive layer 114 of the substrate 110. In some embodiments, the plane structure 140p may extend between the two lateral surface 140s2 and 140s2′ of the shielding layer 140.

The shielding layer 140 of the electronic package 100b is spaced apart from the dielectric structure 112 of the substrate 110 by the encapsulant 130. The shielding layer 140 of the electronic package 100b is not in contact with the junction of the dielectric structure 112 of the substrate 110 and the encapsulant 130. Therefore, the shielding layer 140 of the electronic package 100b may remain intact during the reliability tests at different temperatures, and may assist in blocking the electronic package 100b from interfering signals in the surrounding environment.

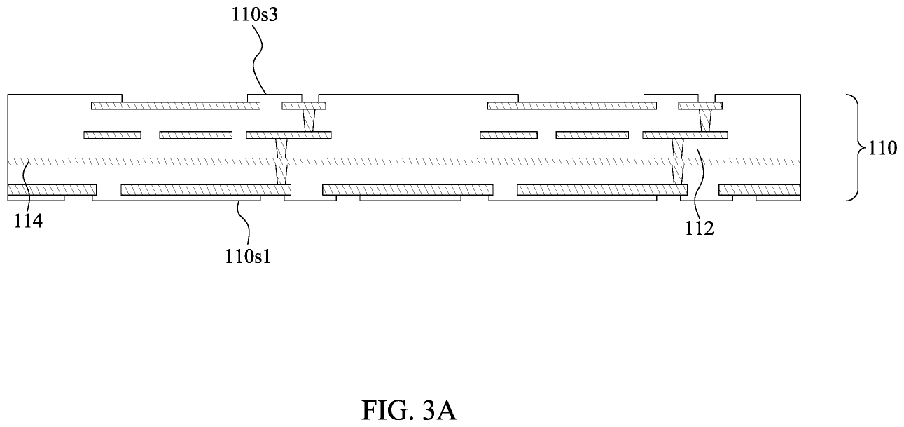

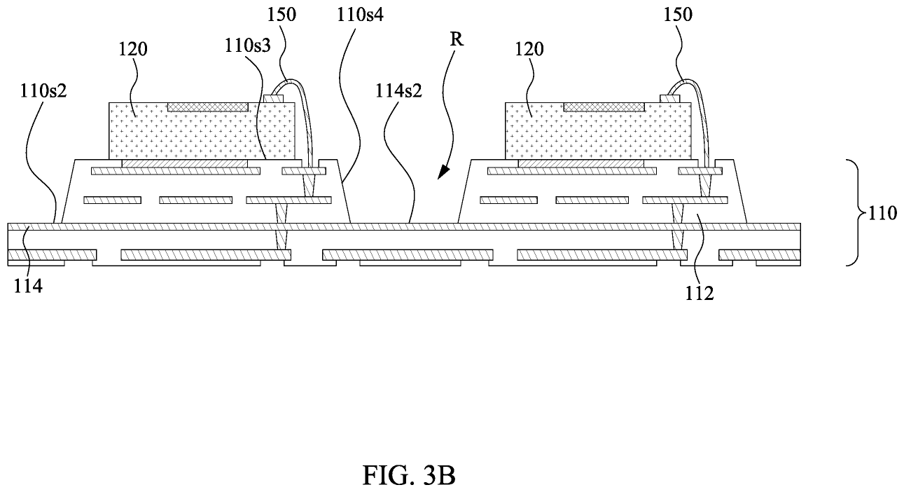

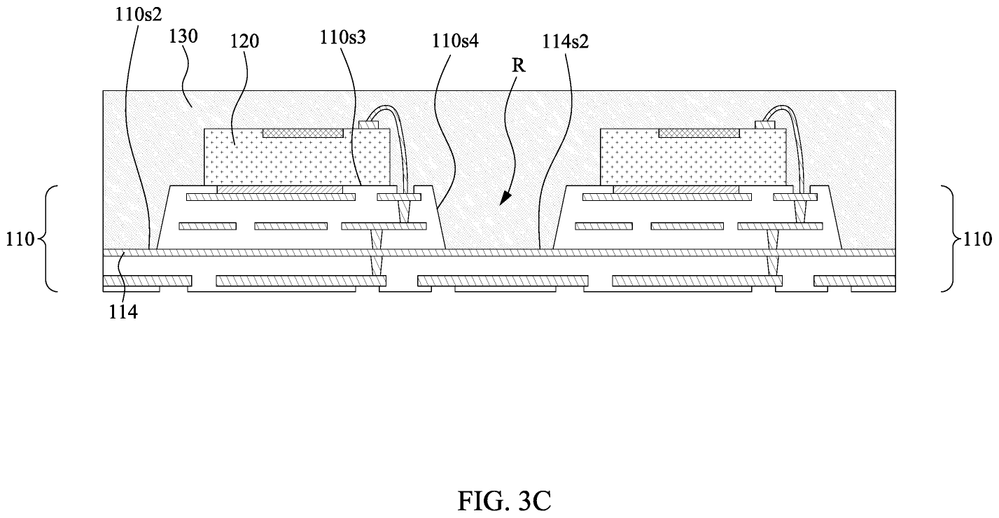

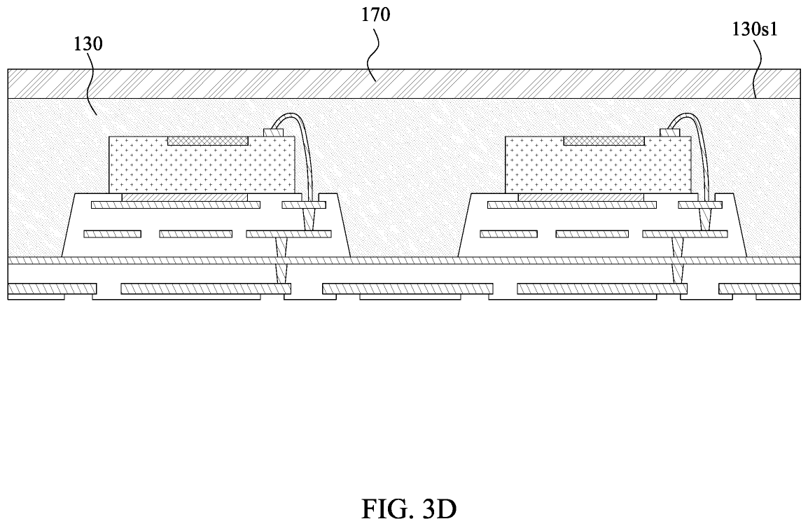

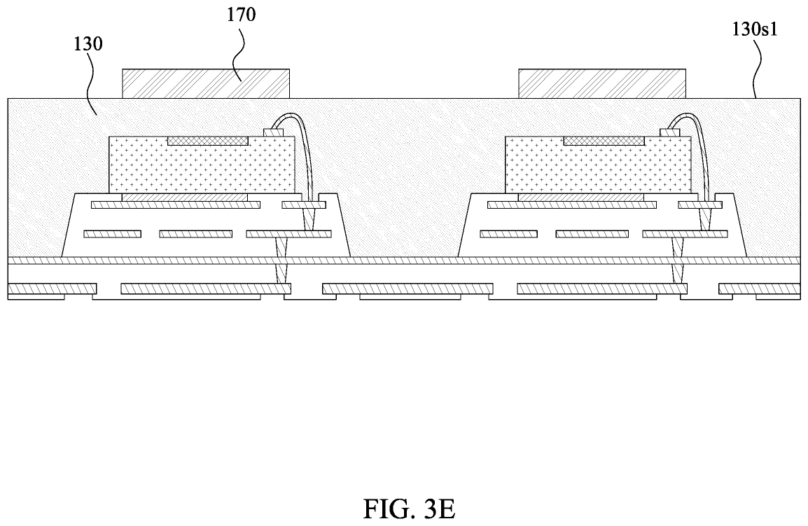

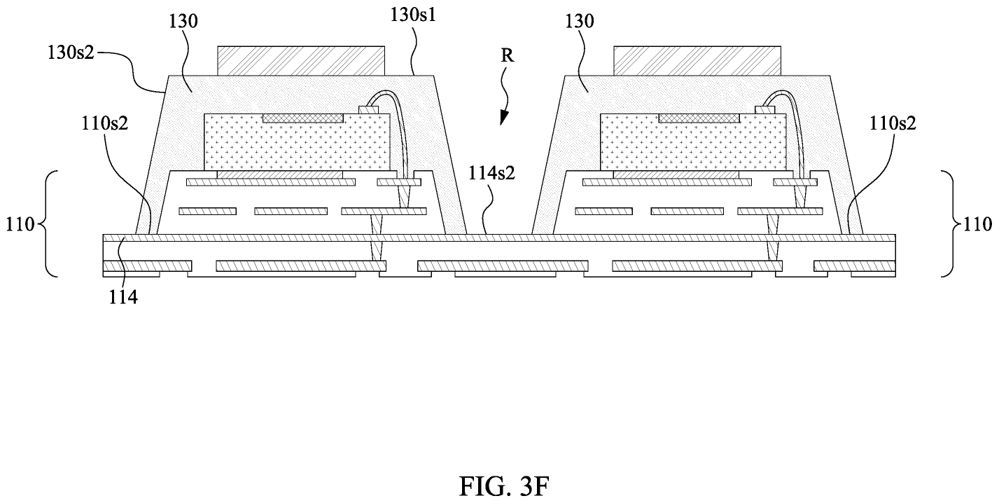

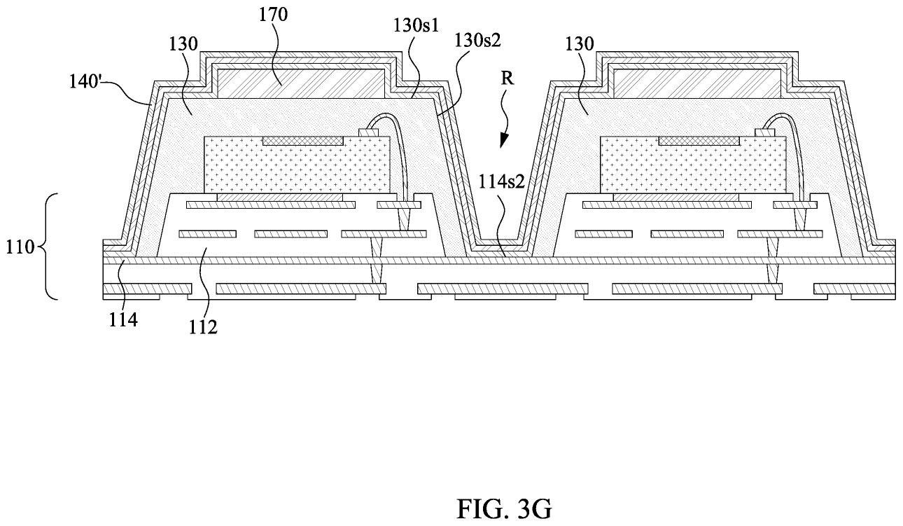

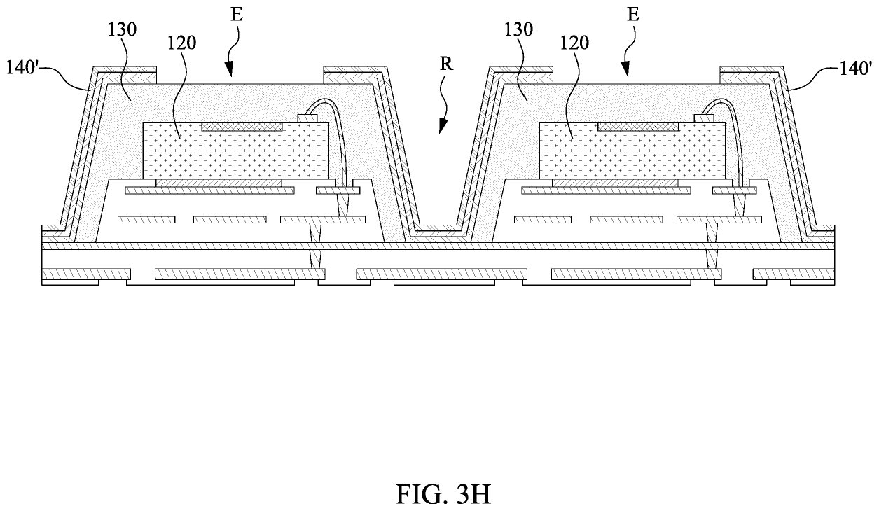

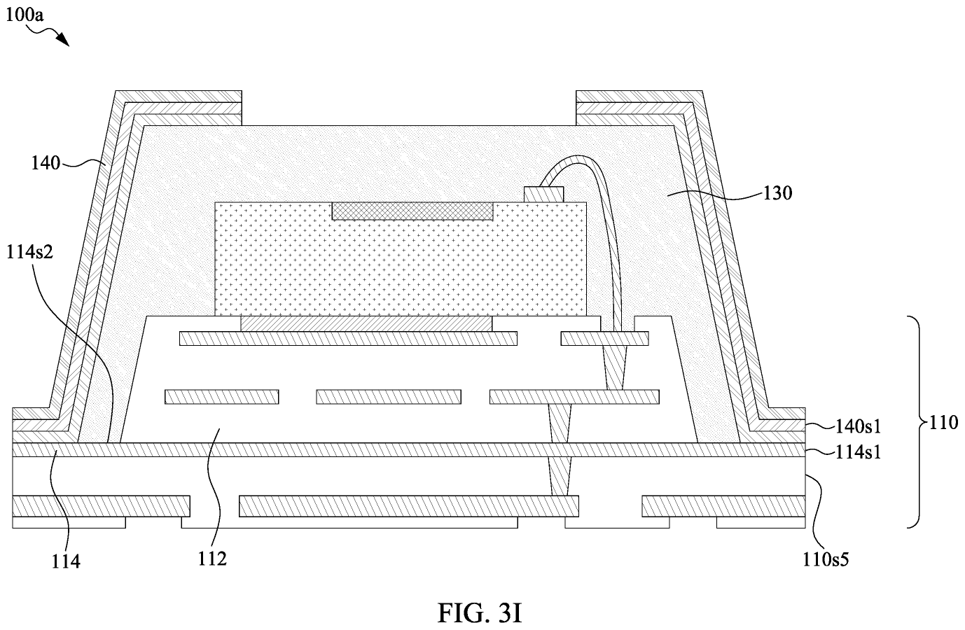

FIG. 3A, FIG. 3B, FIG. 3C, FIG. 3D, FIG. 3E, FIG. 3F, FIG. 3G, FIG. 3H and FIG. 31 illustrate various stages of a method for manufacturing an electronic package 100a in accordance with some embodiments of the present disclosure.

Referring to FIG. 3A, a semiconductor structure including a substrate 110 is provided. the semiconductor structure may include a plurality of repeated units of package structures. The substrate 110 may include a dielectric structure 112 and a conductive layer 114 embedded in the dielectric structure 112. The substrate 110 may have a surface 110s1 and a surface 110s3 on two opposite sides of the substrate 110.

Referring to FIG. 3B, an electronic component 120 may be disposed on the surface 110s3 of the substrate 110 and electrically connected to the substrate 110 through an electrical connector 150. Further, a portion of the substrate 110 may be removed to form a recess R in a peripheral region of each of the repeated units of the package structures. As a result, a portion of a surface 114s2 of the conductive layer 114 is exposed by the recess R. In some embodiments, removing the substrate 110 may include removing a portion of the dielectric structure 112 of the substrate 110. In some embodiments, a first cutting operation may be performed from the surface 110s3 of the substrate 110 to form a surface 110s2 and a surface 110s4 serving as the bottom and sidewall respectively, of the recess R.

Referring to FIG. 3C, an encapsulant 130 may be formed to cover the electronic component 120, the surface 110s2, the surface 110s3, and the surface 110s4 of the substrate 110. The encapsulant 130 may extend into the recess R of the substrate 110. In some embodiments, the encapsulant 130 covers the surface 114s2 of the conductive layer 114.

Referring to FIG. 3D, a mask 170 may be formed on a surface 130s1 of the encapsulant 130. The mask 170 may be configured to define a pattern of a shielding layer formed in subsequent stages. In some embodiments, the mask 170 may include, for example, a photo-sensitive material or other suitable materials. In some embodiments, the mask 170 may include a photoresist, such as a dry film.

Referring to FIG. 3E, the mask 170 is patterned such that a portion of the surface 130s1 of the encapsulant 130 is exposed from the mask 170. In some embodiments, patterning the mask 170 may include disposing a light shielding film (not shown) on the mask 170. The light shielding film may cover a first portion of the mask 170, and a second portion of the mask 170 may be exposed from the light shielding film. In some embodiments, patterning the mask 170 may further include curing the second portion of the mask 170, exposed from the light shielding film, using a light (e.g., ultraviolet (UV) light)). In some embodiments, patterning the mask 170 may further include removing the light shielding film and the first portion of the mask 170 covered by the light shielding film.

Referring to FIG. 3F, a portion of the encapsulant 130 may be removed. In some embodiments, removing the encapsulant 130 may include removing a portion of the encapsulant 130 in the recess R. In some embodiments, a second cutting operation may be performed from the surface 130s1 of the encapsulant 130 to form a surface 130s2, which is oblique with respect to the surface 110s2 of the substrate 110. Further, a portion of the surface 114s2 of the conductive layer 114 is exposed by the encapsulant 130.

Referring to FIG. 3G, a conductive structure 140′ is formed to cover the surface 130s1 and the surface 130s2 of the encapsulant 130, the mask 170, and the surface 114s2 of the conductive layer 114. The conductive structure 140′ conformally covers the recess R formed in the operation of FIG. 3F. The conductive structure 140′ may be in contact with the surface 114s2 of the conductive layer 114. The conductive structure 140′ may be spaced apart from the dielectric structure 112 of the substrate 110 by the encapsulant 130. In some embodiments, the conductive structure 140′ may be formed by, for example, at least one sputter operation. In some embodiments, the conductive structure 140′ may include multiple layers, such as layers 141, 142 and 143 of the conductive structure 140 as discussed above with respect to FIG. 1.

Referring to FIG. 3H, the mask 170 and the conductive structure 140′ above the mask 170 may be removed to form openings E such that signals can be transmitted from or to the electronic component 120 by passing through the opening E and the encapsulant 130. As a result, the shielding layer 140 is produced. In some embodiments, the mask 170 may be removed by a basic solution. The basic solution may include, for example, sodium hydroxide (NaOH).

Referring to FIG. 3I, a singulation process is carried out. The repeated units are divided such that a plurality of electronic packages 100a are produced. In some embodiments, a third cutting operation is performed from the recess R to cut through the conductive structure 140′, the conductive layer 114 and the substrate 110. As a result, the electronic package 100a is formed and each of a surface 140s1 of the shielding layer 140, a surface 110s5 of the substrate 110, and a surface 114s1 of the conductive layer 114 may be substantially coplanar to each other.

In this embodiment, the first cutting operation and the second cutting operation are performed to half cut the substrate 110 and the encapsulant 130, respectively. As a result, the shielding layer 140 may be spaced apart from the dielectric structure 112 of the substrate 110, causing a junction or an interface between the dielectric structure 112 and the encapsulant 130 to be spaced apart from the shielding layer 140. Therefore, the shielding layer 140 of the electronic package 100a may remain intact during the reliability tests at different temperatures, and may assist in blocking the electronic package 100a from interfering light signals in the surrounding environment.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only and that practical implementations of the structures described herein can be spatially arranged in any orientation or manner, provided that the merits of embodiments of this disclosure are not deviated from by such an arrangement.

As used herein, the term “vertical” is used to refer to upward and downward directions, whereas the term “horizontal” refers to directions transverse to the vertical directions.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same as or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces does not exceed 5 μm, 2 μm, 1 μm, or 0.5 μm. A surface can be deemed to be substantially flat if a displacement between the highest point and the lowest point of the surface does not exceed 5 μm, 2 μm, 1 μm, or 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity exceeding approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not necessarily be drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit, and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An electronic package, comprising:
a substrate having a first upper surface, a second upper surface, and a first lateral surface extending between the first upper surface and the second upper surface;
a first electronic component disposed on the substrate;
an encapsulant covering the first electronic component and the first lateral surface of the substrate; and
a shielding layer covering the encapsulant, wherein the shielding layer is spaced apart from the first lateral surface of the substrate.

2. The electronic package of claim 1, wherein the first electronic component is disposed on the first upper surface of the substrate, and the encapsulant covers the first upper surface and the second upper surface of the substrate.

3. The electronic package of claim 1, wherein the shielding layer is in contact with the second upper surface of the substrate.

4. The electronic package of claim 1, wherein the shielding layer is electrically connected to a ground layer of the substrate.

5. The electronic package of claim 1, wherein a conductive layer is embedded in a dielectric structure of the substrate.

6. The electronic package of claim 4, wherein the shielding layer has a surface substantially aligned with a lateral surface of the ground layer.

7. The electronic package of claim 1, wherein the shielding layer defines an opening exposing the first electronic component.

8. The electronic package of claim 1, wherein the substrate further comprises a bottom surface and a second lateral surface extending between the bottom surface and the second upper surface of the substrate, and the shielding layer does not contact the second lateral surface.

9. The electronic package of claim 1, wherein the encapsulant comprises an upper surface and a lateral surface extending between the upper surface of the encapsulant and the second upper surface of the substrate, wherein the lateral surface of the encapsulant is oblique with respect to the second upper surface of the substrate.

10. The electronic package of claim 1, further comprising:
a second electronic component disposed on the substrate, wherein the second electronic component is blocked from the first electronic component by the shielding layer.

11. The electronic package of claim 10, wherein at least one of the first electronic component and the second electronic component comprises an optical sensor.

12. An electronic package, comprising:
a substrate comprising a conductive layer, wherein the substrate defines a recess at a peripheral region of the substrate and the conductive layer is exposed from the recess;
a shielding layer electrically connected to an exposed portion of the conductive layer exposed from the recess; and
an encapsulant disposed between the substrate and the shielding layer and extending into the recess of the substrate.

13. The electronic package of claim 12, wherein the conductive layer of the substrate has an upper surface in contact with the shielding layer.

14. The electronic package of claim 13, wherein the substrate has a first lateral surface, the first lateral surface of the substrate and the upper surface of the conductive layer defines the recess, and the first lateral surface of the substrate is spaced apart from the shielding layer by the encapsulant.

15. The electronic package of claim 14, wherein the first lateral surface of the substrate is oblique with respect to the upper surface of the conductive layer.

16. The electronic package of claim 14, wherein the substrate further comprises a bottom surface and a second lateral surface extending between the bottom surface of the substrate and the upper surface of the conductive layer, and the shielding layer has a surface substantially aligned with the second lateral surface of the substrate.

17. The electronic package of claim 12, further comprising:
a first electronic component and a second electronic component disposed on the substrate, wherein the shielding layer is disposed between the first electronic component and the second electronic component.

18. An electronic package, comprising:
a carrier comprising a conductive layer exposed by a recess at a peripheral region of the carrier; and
an encapsulant covering the carrier and extending into the recess of the carrier.

19. The electronic package of claim 18, further comprising:
a shielding layer electrically connected to the conductive layer.

20. The electronic package of claim 19, wherein a portion of the conductive layer is exposed from the encapsulant.
